(19) United States
(12) Patent Application Publication
(10) Pub. No.: US 2014/0166355 A1
(43) Pub. Date: Jun. 19, 2014

(54) METHOD OF MANUFACTURING PRINTED CIRCUIT BOARD

(71) Applicant: SAMSUNG ELECTRO-MECHANICS CO., LTD., Suwon (KR)

(72) Inventors: Suk Gi Hong, Busan (KR); Jeong Woo Lee, Busan (KR); Going Sik Kim, Busan (KR); Hyo Seung Nam, Suwon (KR)

(73) Assignee: SAMSUNG ELECTRO-MECHANICS CO., LTD., Suwon (KR)

(21) Appl. No.: 13/952,247

(22) Filed: Jul. 26, 2013

(30) Foreign Application Priority Data
Dec. 18, 2012 (KR) 10-2012-0148508

(51) Int. Cl. H05K 3/42; H05K 1/11

(52) U.S. Cl. CPC H05K 3/423; H05K 1/115
USPC 174/264; 29/852

(57) ABSTRACT

Disclosed herein is a method of manufacturing a printed circuit board, the method including: (a) performing a hole processing process on one surface of a core layer to process a first via hole having a predetermined height hl; (b) performing a plating process on one surface of the core layer to form a first via electrode in the first via hole and form a first metal layer on one surface of the core layer; (c) performing a hole processing process on the other surface of the core layer to process a second via hole having a predetermined height h2 exposing a lower surface of the first via electrode to the outside; and (d) performing a plating process on the other surface of the core layer to form a second via electrode in the second via hole and form a second metal layer on the other surface of the core layer.

### CROSS REFERENCE(S) TO RELATED APPLICATIONS

This application claims the foreign priority benefit of Korean Patent Application No. 10-2012-0148508, entitled “Method of Manufacturing Printed Circuit Board” filed on Dec. 18, 2012, which is hereby incorporated by reference in its entirety into this application.

### BACKGROUND OF THE INVENTION

1. Technical Field

The present invention relates to a method of manufacturing a printed circuit board and more particularly, to a method of manufacturing a via electrode for an interlayer connection in the printed circuit board.

2. Description of the Related Art

Recently, miniaturization and technology integration of electronic devices and products in response to the highly functionalized electronic devices and products have gradually developed. Correspondingly, a process of manufacturing a printed circuit board (PCB) used in the electronic devices and the like also requires various changes corresponding to the miniaturization and the technology integration.

A technology trend for a method of manufacturing the printed circuit board has initially developed from a single-side substrate to a double-side substrate and again developed to a multi-layer substrate, and particularly, a manufacturing method so-called a build-up method has recently been developed for manufacturing the multi-layer substrate.

In order to electrically connect between a circuit pattern of each layer and an electronic component in a process of manufacturing the multi-layer substrate, various via holes such as an inner via hole (IVH), a blind via hole (BVH), a plated through hole (PTH), and the like are formed.

The process of forming the via hole according to the related art first forms the via hole in the substrate using a drill or laser, performs a desmear process on a surface of the substrate and an inner periphery surface of the via hole, and then fills an inner space of the via hole with a metal.

In this case, in order to fill the inner space of the via hole with the metal, a fill plating method is used, wherein the fill plating method has a problem in that it is difficult to apply to the via hole having a predetermined size or more. That is, in the case in which the via hole has a large size, a large dimple is generated and the via hole is hardly plated even in the case in which a thickness of plating becomes thicker.

Meanwhile, in the case of the plated through hole, since both upper and lower portions of the hole are opened, it is difficult to fill the metal at a high density. Moreover, in the case in which the surface of the hole is not uniform due to a processing deviation, defects such as a void having an empty hollow shape, a seam, and the like may be generated during plating. As a result, this deteriorates yield and reliability of the printed circuit board.

In this connection, Korean Patent Laid-Open Publication No. 10-2005-0098579 (hereinafter, referred to as the related art document) discloses a method of manufacturing a via hole, the method performing forming a first via hole, filling and applying an insulating paste onto a surface of a panel and the first via hole, and processing a second via hole having a diameter smaller than that of the first via hole in the first via hole filled with the insulating paste.

However, according to the technology of the related art document as described above, a narrow via pitch may be implemented, but since the hole penetrating through the entire substrate is processed and the plating is then performed at the time of processing the via hole, the above-mentioned problem is not solved.

In addition, a number of processes need to be performed as compared to the via hole processing according to the related art, thus productivity is decreased.

[Related Art Document]

[Patent Document]

(Patent Document 1) Patent Document: Korean Patent Laid-Open Publication No. 10-2005-0098579

### SUMMARY OF THE INVENTION

An object of the present invention is to provide a printed circuit board including a via electrode formed thereon without defects such as a void and the like by performing a process of forming a via electrode on both sides of a core layer.

According to an exemplary embodiment of the present invention, there is provided a method of manufacturing a printed circuit board, the method including: (a) performing a hole processing process on one surface of a core layer to process a first via hole having a predetermined height h1; (b) performing a plating process on one surface of the core layer to form a first via electrode in the first via hole and form a first metal layer on one surface of the core layer; (c) performing a hole processing process on the other surface of the core layer to process a second via hole having a predetermined height h2 exposing a lower surface of the first via electrode to the outside; and (d) performing a plating process on the other surface of the core layer to form a second via electrode in the second via hole and form a second metal layer on the other surface of the core layer.

The height hl of the first via hole may have a value corresponding to a half of a thickness of the core layer.

Before performing step (b), a plating prevention film may be bonded to the other surface of the core layer and after performing step (b), the plating prevention film may be delaminated.

Before performing step (d), a plating prevention film may be bonded to a surface of the first metal layer and after performing step (d), the plating prevention film may be delaminated.

The hole processing process in step (a) or step (c) may use any one of a CNC drill, a CO₂ laser drill, and a YAG laser drill.

The first and second via holes may have a tapered shape in which diameter thereof becomes narrower toward an inner portion of the core layer.

The plating process in step (b) or step (d) may be performed by forming a seed layer on an inner wall of the first via hole or an inner wall of the second via hole as well as on a surface of the core layer, and performing an electrolysis plating using the seed layer as a leading wire.

After performing step (d), the first and second metal layers may be selectively etched so as to form a circuit pattern.

### BRIEF DESCRIPTION OF THE DRAWINGS

FIGS. 1 to 9 are process views sequentially showing a method for manufacturing a printed circuit board according to an exemplary embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals throughout the description denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

FIG. 9 is a cross-sectional view of a printed circuit board finally completed according to the exemplary embodiment of the present invention. Referring to FIG. 9, the printed circuit board according to the exemplary embodiment of the present invention may include a core layer 100, a first via electrode 120, and a second via electrode 160.

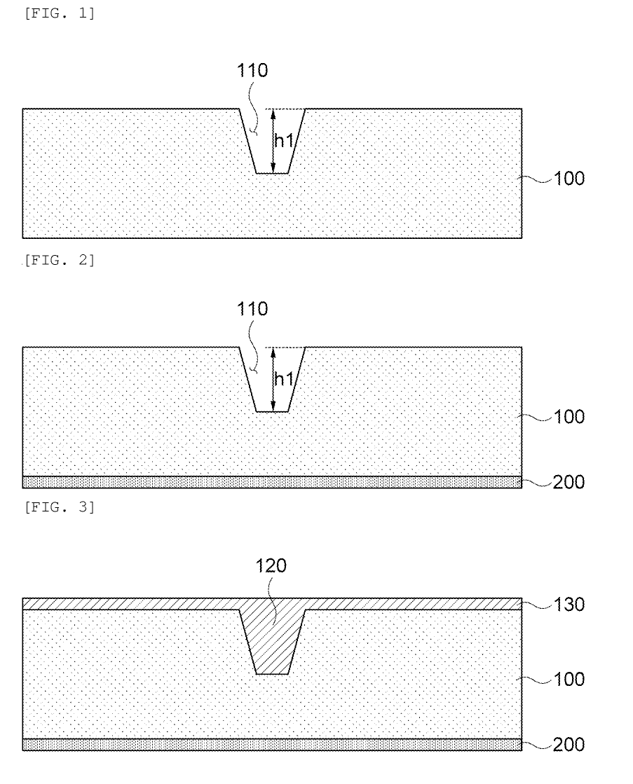

The first via electrode 120 may be formed by filling a metal material in a first via hole 110 (110 in FIG. 1) having a predetermined height h1 formed on one surface of the core layer 100.

As described above, since the first via electrode 120 is formed in the first via hole 110 in a shape in which it does not completely penetrate through the core layer 100 and is opened only up to the predetermined height h1, such that a lower portion thereof is not opened and is closed, thereby making it possible to fill at a high density at the time of filling the metal material. Therefore, the first via electrode 120 may be formed without defects such as a void and the like.

In addition, the second via electrode 160 may be formed by filling the metal material in a second via hole 150 (150 in FIG. 5) having a predetermined height h2 formed on the other surface of the core layer 100 and exposing a lower surface of the first via electrode 120 to the outside.

Since the second via electrode 160 is also formed in the second via hole 150 in a shape in which it does not completely penetrate through the core layer 100 and is opened only up to the predetermined height h2, such that a lower portion thereof is not opened and is closed, similar to the first via electrode 120, thereby making it possible to fill at a high density at the time of filling the metal material. Therefore, the second via electrode 160 without defects such as a void and the like may be formed.

Here, since the second via hole 150 exposes the lower surface of the first via electrode 120 to the outside, the second via electrode 160 and the first via electrode 120 may be bonded to each other while having a flat interface. It allows circuit patterns 130a and 170a formed on the surface of the core layer 100 to be electrically connected to each other.

Hereinafter, a method of manufacturing a printed circuit board according to the exemplary embodiment of the present invention will be described with reference to FIGS. 1 to 9.

The method of manufacturing the printed circuit board according to the exemplary embodiment of the present invention first performs performing a hole processing process on one surface of the core layer 100 to process the first via hole 110, as shown in FIG. 1.

Here, the core layer 100 may be a thermosetting or thermo-plastic polymer substrate, a ceramic substrate, an organic-inorganic complex material substrate, or a glass fiber impregnated substrate and may include an epoxy based insulating resin or a polyimide based resin in the case of including a polymer resin.

Alternatively the core layer 100 may be a copper clad laminate (CCL) having a copper foil laminated on one surface or both surfaces of an insulating plate made of the above-mentioned insulating materials. However, the drawings does not separately show the copper foil of the copper clad laminate, but shows a case in which the copper foil is incorporated in the core layer 100.

At the time of processing the first via hole 110, a laser drill such as YAG laser, CO₂ laser, or the like, or a machinery drill such as a computer numerical control (CNC) drill or the like may be used.

In the case in which the core layer 100 is the copper clad laminate (CCL), the copper foil of a portion in which the first via hole 110 is formed is etched and the insulating plate is then removed using the CO₂ laser drill. In the case in which the YAG laser drill is used, the copper foil and the insulating plate configuring the copper clad laminate (CCL) may be simultaneously removed.

In this case, the core layer 100 is removed only up to a predetermined depth h1 so that the core layer 100 is not penetrated. Therefore, the first via hole 110 has a predetermined height h1 and has a shape in which upper and lower portions thereof are not completely opened to the outside, that is, the upper portion thereof is opened on one surface of the core layer 100 and the lower portion thereof is closed by the core layer 100.

The object of the present invention is to form the via electrode for an interlayer connection by using a divided plating, wherein the height h1 of the first via hole 110 may be set to a value corresponding to a half of a thickness of the core layer 100.

Meanwhile, the first via hole 110 formed by the laser drill has a tapered shape in which a diameter thereof becomes narrower toward an inner portion of the core layer 100.

In the case in which the first via hole 110 having a predetermined height h1 is processed on one surface of the core layer 100, as shown in FIG. 3, a plating process is performed on one surface of the core layer 100, such that the first via electrode 120 is formed in the first via hole 110 and a first metal layer 130 is formed on one surface of the core layer 100.

Since the core layer 100 is made of an insulating material and an inner wall of the first via hole 110 is also made of the insulating material of the core layer 100, in order to give conductive property thereto, electroless plating is performed so as to form a seed layer (not shown in the drawings) on the inner wall of the first via hole 110 as well as the surface of the core layer 100.

In addition, in the case in which electrolysis plating is performed using the seed layer as a leading wire, the first metal layer 130 is plated on one surface of the core layer 100 and a metal is filled in the first via hole 110, such that the first via electrode 120 is formed.

In this case, since the lower portion of the first via hole 110 has a shape in which it is not opened and is closed by the core layer 100, the metal filled in the first via hole 110 at the time of the electrolysis plating may be densified and filled. Therefore, the first via electrode 120 without defects such as a void and the like therein may be formed.

Meanwhile, before performing the plating process, bonding a plating prevention film 200 to the other surface of the core layer 100 may be further performed, as shown in FIG. 2.

Since the electroless plating for forming the seed layer is performed in a state in which the core layer 100 is deposited in a plating bath filled with a plating solution, in the case in which the electroless plating is performed in a state in which the plating prevention film 200 is bonded to the other surface of the core layer 100, as shown in FIG. 2, it is possible to prevent the seed layer from being formed on the other surface of the core layer 100. The reason for preventing the seed layer from being formed on the other surface of the core layer 100 will be described below.

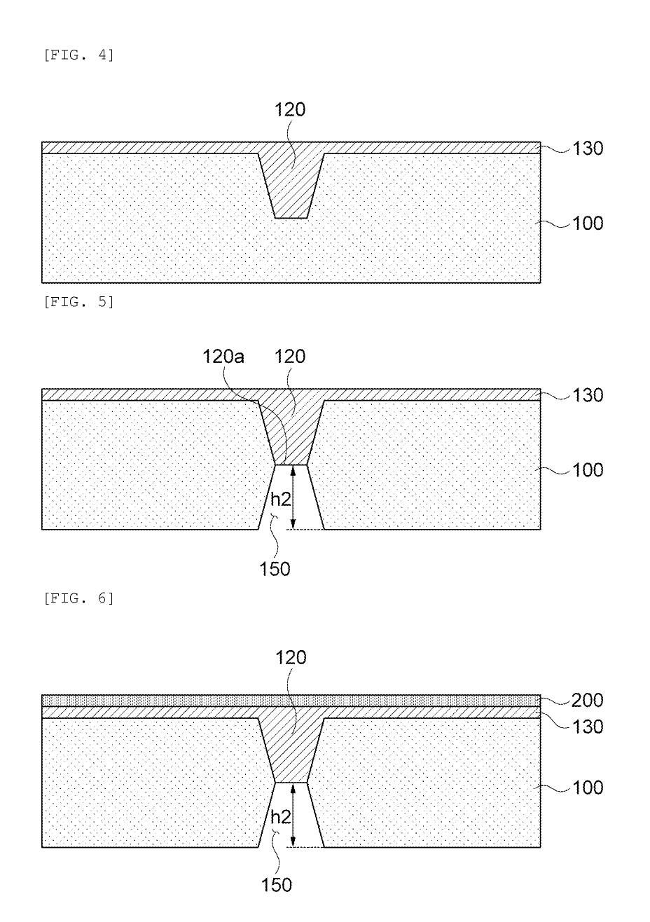

After completing the plating process, the plating prevention film 200 is delaminated as shown in FIG. 4 and the hole processing process is performed on the other surface of the core layer 100 as shown in FIG. 5, such that the second via hole 150 is processed.

The second via hole 150 may be formed using the laser drill such as YAG laser, CO₂ laser, or the like, or the machinery drill such as the CNC drill or the like similar to the first via hole 110.

In this case, drilling is performed at a position at which the second via hole 150 coincides with the first via electrode 120 on a vertical line. Therefore, the core layer 100 is not penetrated and is opened only up to a predetermined depth h2, such that a lower surface 120a of the first via electrode 120 is exposed to the outside.

That is, the second via hole 150 has a predetermined height h2 and has a shape in which upper and lower portions thereof are not completely opened to the outside, that is, the upper portion thereof is opened on the other surface of the core layer 100 and the lower portion thereof is closed by the first via electrode 120.

Meanwhile, in the case in which the seed layer is formed on the other surface of the core layer 100 because the plating prevention film 200 is not bonded to the other surface of the core layer 100 before performing the plating process for forming the first via electrode 120 and the first metal layer 130, when the second via hole 150 is processed using CO₂ laser, additional etching of the seed layer at a portion in which the second via hole 150 is formed needs to be performed.

In addition, even in the case in which the seed layer and the core layer 100 are simultaneously processed using the YAG laser, the seed layer is dissolved by a high temperature drill condition, such that an inner wall of the second via hole 150 is stained with a foreign material. Therefore, in order to remove the foreign material, since an additional process needs to be performed, process efficiency may be decreased. Therefore, before performing the plating process for forming the first via electrode 120 and the first metal layer 130, the plating prevention film 200 is bonded to the other surface of the core layer 100 as shown in FIG. 2.

Once the second via hole 150 is formed, the plating prevention film 200 is bonded to the surface of the first metal layer 130, the seed layer is formed on an inner wall of the second via hole 150 as well as the surface of the core layer 100 by the electroless plating, and the electrolysis plating is then performed using the seed layer as the leading wire, as shown in FIG. 6, such that a second via electrode 160 is formed in the second via hole 150 and a second metal layer 170 is formed on the other surface of the core layer 100.

In this case, since the lower portion of the second via hole 150 has a shape in which it is not opened to the outside and is closed by the first via electrode 120, the metal filled in the second via hole 150 at the time of the electrolysis plating may be densified and filled. Therefore, the second via electrode 160 without defects such as a void and the like therein may be formed similar to the first via electrode 120.

As described above, once the second via electrode 160 is formed, the second via electrode 160 is bonded to the lower surface 120a of the first via electrode 120. Therefore, interlayer electrical conduction is performed through the first and second via electrodes 120 and 160.

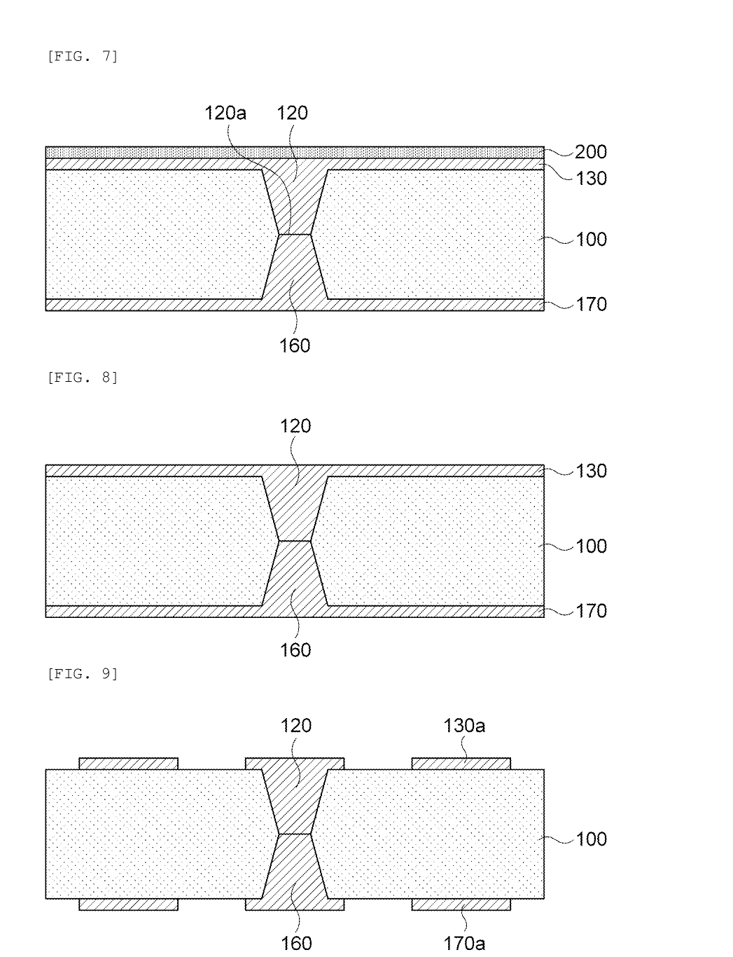

Once the second via electrode 160 and the second metal layer 170 are formed, as shown in FIG. 8, the plating prevention film 200 is delaminated from the other surface of the core layer 100 and the first metal layer 130 and the second metal layer 170 are selectively etched, such that the printed circuit board having circuit patterns 130a and 170a formed on the surface of the core layer 100 according to the exemplary embodiment of the present invention may be finally completed as shown in FIG. 9.

According to the exemplary embodiment of the present invention, the via electrode without defects such as the void and the like may be formed by a simple method, such that the printed circuit board having reliability may be provided at low cost.

The above detailed description has illustrated the present invention. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A printed circuit board, comprising:
a core layer;
a first via electrode filled and formed in a first via hole having a predetermined height h1 formed on one surface of the core layer; and
a second via electrode formed on the other surface of the core layer and filled and formed in a second via hole having a predetermined height h2 exposing a lower surface of the first via electrode to the outside.

2. The printed circuit board according to claim 1, wherein the first via electrode and the second via electrode are bonded to each other while having a flat interface.

3. A method of manufacturing a printed circuit board, the method comprising:
(a) performing a hole processing process on one surface of a core layer to process a first via hole having a predetermined height h1;
(b) performing a plating process on one surface of the core layer to form a first via electrode in the first via hole and form a first metal layer on one surface of the core layer;
(c) performing a hole processing process on the other surface of the core layer to process a second via hole having a predetermined height h2 exposing a lower surface of the first via electrode to the outside; and
(d) performing a plating process on the other surface of the core layer to form a second via electrode in the second via hole and form a second metal layer on the other surface of the core layer.

4. The method according to claim 3, wherein the height hl of the first via hole has a value corresponding to a half of a thickness of the core layer.

5. The method according to claim 3, wherein before performing step (b), a plating prevention film is bonded to the other surface of the core layer and after performing step (b), the plating prevention film is delaminated.

6. The method according to claim 3, wherein before performing step (d), a plating prevention film is bonded to a surface of the first metal layer and after performing step (d), the plating prevention film is delaminated.

7. The method according to claim 3, wherein the hole processing process in step (a) or step (c) uses any one of a CNC drill, a CO₂ laser drill, and a YAG laser drill.

8. The method according to claim 3, wherein the first and second via holes have a tapered shape in which diameter thereof becomes narrower toward an inner portion of the core layer.

9. The method according to claim 3, wherein the plating process in step (b) or step (d) is performed by forming a seed layer on an inner wall of the first via hole or an inner wall of the second via hole as well as on a surface of the core layer, and performing an electrolysis plating using the seed layer as a leading wire.

10. The method according to claim 3, wherein after performing step (d), the first and second metal layers are selectively etched so as to form a circuit pattern.
